(19) United States
(12) Patent Application Publication
(10) Pub. No.: US 2025/0311147 A1
(43) Pub. Date: Oct. 2, 2025

(54) MODULES, SYSTEMS, AND METHODS FOR COOLING OPTICS AND COPPER PACKAGES

(71) Applicant: MELLANOX TECHNOLOGIES, LTD., Yokneam (IL)

(72) Inventors: John FRANZ, Tomball, TX (US); Tahir CADER, Spokane Valley, WA (US); Elad MENTOVICH, Tel Aviv (IL); Eyal BABISH, Zichron Yaakov (IL); Boaz ATIAS, Maale Adumim (IL)

(73) Assignee: MELLANOX TECHNOLOGIES, LTD., Yokneam (IL)

(21) Appl. No.: 18/616,960

(22) Filed: Mar. 26, 2024

(51) Int. Cl. H05K 7/20

(52) U.S. Cl. CPC H05K 7/20254; H05K 7/20336

(57) ABSTRACT

Modules, systems, and methods for cooling optics and copper packages are described herein. Some embodiments of the present invention may be directed to cooling systems for cooling electronic modules (e.g., network switches) that include optics and copper packages. An electronic module may include a substrate having a first surface defining a central portion and a peripheral portion. A main die (e.g., an ASIC) may be positioned on the central portion of the first surface, and a plurality of optical modules may be positioned on the peripheral portion of the first surface (e.g., around the main die). A cooling system may include a cold plate thermally coupled to the main die that includes a fluid inlet and a fluid outlet for receiving and releasing a cooling fluid. The cooling system may also include multiple cooling conduits, each thermally coupling the cold plate to an optical module.

### FIELD OF THE INVENTION

The present invention relates to modules, systems, and methods for cooling optics and copper packages.

### BACKGROUND

Copper-based interconnections provide low cost and low power options for linking servers and switches together. To reduce latency and signal losses, cable lengths of less than a meter should be maintained. Pluggable active optical modules provide another linking solution at high data speeds (e.g., 200 Gb/s to 400 Gb/s).

### SUMMARY

The following presents a simplified summary of one or more embodiments of the present invention, in order to provide a basic understanding of such embodiments. This summary is not an extensive overview of all contemplated embodiments and is intended to neither identify key or critical elements of all embodiments nor delineate the scope of any or all embodiments. This summary presents some concepts of one or more embodiments of the present invention in a simplified form as a prelude to the more detailed description that is presented later.

In one aspect, the present invention is directed to a cooling system that include a cold plate, a cooling conduit, and a coupling block. The cold play may be thermally coupled to a main die and may define a fluid inlet and a fluid outlet for receiving and releasing, respectively, a cooling fluid. The cooling conduit may thermally couple the cold plate to an optical module. The coupling block may be positioned on the cold plate and may rotatably support the cooling conduit. The coupling block may thermally couple the cooling conduit to the cold plate. The coupling block and the cooling conduit may be configured to permit rotation of the cooling conduit between a cooling position in which the cooling conduit is proximate the optical module and an access position in which the cooling conduit is spaced from the optical module.

In some embodiments, the cold plate may be thermally coupled to a top die surface of the main die, where the top die surface is opposite a die attachment surface positioned on a central portion of a surface of a substrate. Additionally, or alternatively, the cooling conduit, when in the cooling position, may be thermally coupled to a top module surface of the optical module, where the top module surface of the optical module is opposite a module attachment surface positioned on a peripheral portion of the surface of the substrate.

In some embodiments, the cooling system may include a satellite plate positioned over a top module surface of the optical module.

In some embodiments, the satellite plate may include a satellite support, where the cooling conduit includes a heat pipe, and where a portion of the heat pipe is positioned between the top module surface and the satellite support. Additionally, or alternatively, the coupling block may include a pin-and-socket structure configured to receive and rotatably support the heat pipe.

In some embodiments, the satellite plate may include a satellite cold plate, and the cooling conduit may include a first fluid hose and a second fluid hose. Additionally, or alternatively, the coupling block may include a fluid coupling block configured to provide a portion of the cooling fluid from the fluid inlet of the cold plate to the first fluid hose and to provide the portion of the cooling fluid from the second fluid hose to the fluid outlet of the cold plate. In some embodiments, the satellite cold plate may define a passage extending therethrough, where the first fluid hose is configured to provide the portion of the cooling fluid from the coupling block to a first end of the passage, and where the second fluid hose is configured to provide the portion of the cooling fluid from a second end of the passage to the coupling block.

In some embodiments, the cooling conduit may include multiple cooling conduits each thermally coupling the cold plate to a respective optical module of multiple optical modules positioned on a peripheral portion of a surface of a substrate. Additionally, or alternatively, the coupling block may include multiple coupling blocks each positioned on the cold plate and rotatably supporting a respective cooling conduit of the multiple cooling conduits, where each coupling block thermally couples the respective cooling conduit to the cold plate, and where each coupling block and its respective cooling conduit are configured to permit rotation of the cooling conduit between a respective cooling position in which the respective cooling conduit is proximate the respective optical module and a respective access position in which the respective cooling conduit is spaced from the respective optical module. In some embodiments, the multiple cooling conduits may include heat pipes.

In some embodiments, the cooling conduit may include a first heat pipe, and the coupling block may include a first coupling block. Additionally, or alternatively, the cooling system may include a second heat pipe thermally coupling the cold plate to the optical module, and a second coupling block positioned on the cold plate and rotatably supporting the second heat pipe, where the second coupling block thermally couples the second heat pipe to the cold plate, and where the second coupling block and the second heat pipe are configured to permit rotation of the second heat pipe between a second cooling position in which the second heat pipe is proximate the optical module and a second access position in which the second heat pipe is spaced from the optical module.

In some embodiments, the cooling conduit may include a closed-loop thermosiphon.

In some embodiments, the coupling block may include an opening for receiving the cooling conduit, where the opening has an inner surface adjacent the cooling conduit, a pair of O-ring seals disposed between the inner surface and the cooling conduit, and a thermal transfer medium disposed between the O-ring seals and between the inner surface and the cooling conduit. Additionally, or alternatively, the cooling system and/or the coupling block may include one or more interface contacts disposed between the O-ring seals and between an outer surface of the cooling conduit and the thermal transfer medium. In some embodiments, the thermal transfer medium may include liquid metal, thermal grease, and/or the like. Additionally, or alternatively, the thermal transfer medium may be sealed within the opening.

In another aspect, the present invention is directed to an electronic module. The electronic module may include a substrate having a first surface defining a central portion and a peripheral portion and a main die positioned on the central portion of the first surface. The electronic module may include a plurality of optical modules positioned on the peripheral portion of the first surface, and a cold plate thermally coupled to the main die, where the cold plate defines a fluid inlet and a fluid outlet for receiving and releasing, respectively, a cooling fluid. The electronic module may include multiple cooling conduits each thermally coupling the cold plate to an optical module of the plurality of optical modules and multiple coupling blocks positioned on the cold plate and rotatably supporting a respective cooling conduit of the multiple cooling conduits. Each coupling block may thermally couple the respective cooling conduit to the cold plate. Each coupling block and its respective cooling conduit may be configured to permit rotation of the respective cooling conduit between a respective cooling position in which the respective cooling conduit is proximate a respective optical module and a respective access position in which the respective cooling conduit is spaced from the respective optical module.

In some embodiments, the multiple cooling conduits may include heat pipes configured to passively cool the plurality of optical modules.

In some embodiments, the electronic module may include a satellite cold plate positioned over top module surfaces of the plurality of optical modules, and the multiple cooling conduits, the satellite cold plate, and the multiple coupling blocks may be configured to actively cool the plurality of optical modules using the cooling fluid.

In some embodiments, the multiple cooling conduits may include closed-loop thermosiphons.

In another aspect, the present invention is directed to a method of cooling components of an electronic module. The method may include thermally coupling a cold plate to a plurality of optical modules positioned on a peripheral portion of a substrate using multiple cooling conduits, where the cold plate is thermally coupled to a main die positioned on a central portion of the substrate. The method may include providing cooling fluid to the cold plate to cool the main die and the plurality of optical modules.

In some embodiments, the method may include rotatably coupling a cooling conduit of the multiple cooling conduits to the cold plate such that the cooling conduit is configured to rotate into thermal engagement with one or more optical modules of the plurality of optical modules and away from the one or more optical modules.

In some embodiments, the method may include conveying, via coupling blocks and the multiple cooling conduits, the cooling fluid from the cold plate to one or more satellite cold plates thermally coupled to one or more optical modules of the plurality of optical modules.

In some embodiments, each cooling conduit may be thermally coupled to the cold plate by a respective coupling block positioned on the cold plate.

The features, functions, and advantages that have been discussed may be achieved independently in various embodiments of the present invention or may be combined with yet other embodiments, further details of which may be seen with reference to the following description and drawings.

### BRIEF DESCRIPTION OF THE DRAWINGS

Having thus described embodiments of the invention in general terms, reference will now be made in the accompanying drawings, wherein:

FIG. 1A is a top view of an electronic module, in accordance with an embodiment of the invention;

FIG. 1B is a top view of a cooling system for the electronic module of FIG. 1A, in accordance with an embodiment of the invention;

FIGS. 1C-1F are top views of portions of a cooling system, in accordance with embodiments of the invention;

FIGS. 1G and 1H are side views of portions of the electronic module of FIG. 1A and the cooling system of FIG. 1B, in accordance with an embodiment of the invention;

FIG. 1I is a top view of a portion of a cooling system, in accordance with an embodiment of the invention;

FIG. 2A is a cross-sectional side view of a portion of an electronic module and a portion of a cooling system, in accordance with an embodiment of the invention;

FIG. 2B is a cross-sectional perspective view of a coupling block, in accordance with an embodiment of the invention;

FIG. 3A is a top view of an electronic module, in accordance with an embodiment of the invention;

FIG. 3B is a top view of a cooling system for the electronic module of FIG. 3A, in accordance with an embodiment of the invention;

FIG. 3C is a cross-sectional side view of a portion of the electronic module of FIG. 3A and a portion of the cooling system of FIG. 3B;

FIGS. 3D and 3E are side views of portions of the electronic module of FIG. 3A and the cooling system of FIG. 3B, in accordance with an embodiment of the invention; and

FIG. 4 is a flowchart illustrating a method of cooling components of an electronic module, in accordance with an embodiment of the invention.

### DETAILED DESCRIPTION OF EMBODIMENTS OF THE INVENTION

Embodiments of the present invention will now be described more fully hereinafter with reference to the accompanying drawings, in which some, but not all, embodiments of the invention are shown. Indeed, the invention may be embodied in many different forms and should not be construed as limited to the embodiments set forth herein; rather, these embodiments are provided so that this disclosure will satisfy applicable legal requirements. Where possible, any terms expressed in the singular form herein are meant to also include the plural form and vice versa, unless explicitly stated otherwise. Also, as used herein, the term “a” and/or “an” shall mean “one or more,” even though the phrase “one or more” is also used herein. Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, a combination of related and unrelated items, etc.), and may be used interchangeably with “one or more.” Where only one item is intended, the phrase “only one” or similar language is used. Also, as used herein, the terms “has,” “have,” “having,” or the like are intended to be open-ended terms. Furthermore, when it is said herein that something is “based on” something else, it may be based on one or more other things as well. In other words, unless expressly indicated otherwise, as used herein “based on” means “based at least in part on” or “based at least partially on.” Also, as used herein, the term “or” is intended to be inclusive when used in a series and may be used interchangeably with “and/or,” unless explicitly stated otherwise (e.g., if used in combination with “either” or “only one of”). Like numbers refer to like elements throughout. No element, act, or instruction used herein should be construed as critical or essential unless explicitly described as such.

As noted above, copper-based interconnections provide low cost and low power options for linking servers and switches together. To reduce latency and signal losses, cable lengths of less than a meter should be maintained. Pluggable active optical modules provide another linking solution at high data speeds (e.g., 200 Gb/s to 400 Gb/s). However, with increases in power, cooling pluggable active optical modules becomes complex. To address the signal issues and interconnection length restrictions of passive copper and to avoid the challenges of pluggable active optical modules at the bulkhead, optical modules are being integrated onto the switch motherboard (referred to as “Mid Board Optics”) and moving closer to the main die (e.g., an ASIC) with three-dimensional co-packed optics (CPO).

With more integration of functionality on and near the main die, heat fluxes on the motherboard are complex and less uniform, and the heat fluxes are not only generated within the main die but also by nearby optical modules. Providing cooling to handle such heat fluxes is further complicated due to space congestion (e.g., components positioned proximate each other), power densities, sensitive cabling attached to components, and/or the like.

Some embodiments of the present invention are directed to modules, systems, and methods for cooling optics and copper packages. In one aspect, the present invention is directed to cooling systems for cooling electronic modules (e.g., network switches) that include optics and copper packages. In some embodiments, an electronic module may include a substrate having a first surface defining a central portion and a peripheral portion. A main die (e.g., an ASIC) may be positioned on the central portion of the first surface. The electronic module may also include a plurality of optical modules positioned on the peripheral portion of the first surface (e.g., around the main die).

A cooling system for the electronic module may include a cold plate thermally coupled to the main die (e.g., disposed on the main die) that includes a fluid inlet and a fluid outlet for receiving and releasing a cooling fluid. The cooling system may also include multiple cooling conduits, each thermally coupling the cold plate to an optical module, as well as multiple coupling blocks positioned on the cold plate. Each coupling block may thermally couple a respective cooling conduit to the cold plate and rotatably support the respective cooling conduit such that the respective cooling conduit is capable of rotation away from the optical module (e.g., to permit access to the optical module).

The coupling blocks may include openings for receiving the cooling conduits, pairs of O-ring seals between inner surfaces of the openings and the cooling conduits, and a thermal transfer medium (e.g., liquid metal, thermal grease, and/or the like) disposed between the inner surface and the cooling conduit. The thermal transfer medium may be sealed within the opening (e.g., by the O-ring seals). The coupling blocks may include one more interface contacts disposed between the O-ring seals.

In some embodiments, the cooling conduits may include heat pipes configured to passively cool the optical modules. The heat pipes may have a variety of configurations, and portions of the heat pipes may be positioned between a top surface of one or more optical modules and a satellite support that secures the optical modules to the substrate. In such embodiments, the coupling blocks may be pin-and-socket structures for receiving and rotatably supporting the heat pipes.

In some embodiments, the cooling system may actively cool the optical modules. In such embodiments, the cooling system may include one or more satellite cold plates positioned on a top surface of one or more optical modules, the cooling conduits may include fluid hoses, and the coupling blocks may include fluid coupling blocks. The fluid coupling blocks and the fluid hoses may be configured to convey cooling fluid from the cold plate to one end of a passage extending through the satellite cold plate and to convey the cooling fluid from the other end of the passage to the cold plate. In this way, a portion of the cooling fluid from the cold plate is used to actively cool the optical modules.

In some embodiments, the cooling conduits may include closed-loop thermosiphons rotatably coupled to the cold plate by the coupling block. In such embodiments, the closed-loop thermosiphons may convey heat from the optical modules to the cold plate in a closed-loop system to reduce the risk of leaks.

In another aspect, the present invention is directed to a method of cooling components of an electronic module. The method may include thermally coupling a cold plate to a plurality of optical modules positioned on a peripheral portion of a substrate using multiple cooling conduits, where the cold plate is thermally coupled to a main die positioned on a central portion of the substrate. The method may include providing cooling fluid to the cold plate to cool the main die and the plurality of optical modules. Each cooling conduit may be thermally coupled to the cold plate by a respective coupling block positioned on the cold plate, and each cooling conduit may be rotatably supported by its respective coupling block such that the respective cooling conduit is capable of rotation away from an optical module of the plurality of optical modules. The method may further include rotating a cooling conduit away from one or more optical modules of the plurality of optical modules, and, after rotating the cooling conduit away from the one or more optical modules, rotating the cooling conduit toward the one or more optical modules. In some embodiments, the method may include conveying, via coupling blocks and the multiple cooling conduits, the cooling fluid from the cold plate to one or more satellite cold plates thermally coupled to one or more optical modules of the plurality of optical modules.

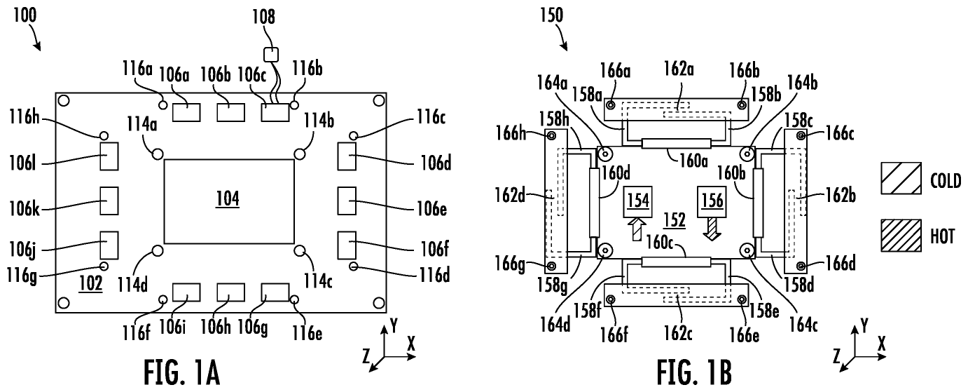

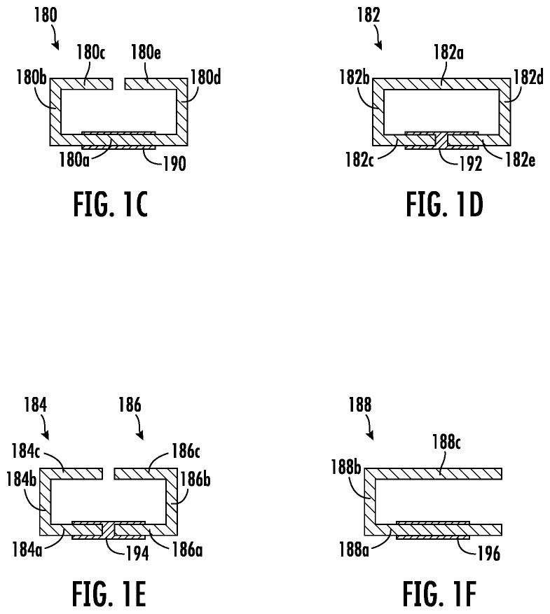

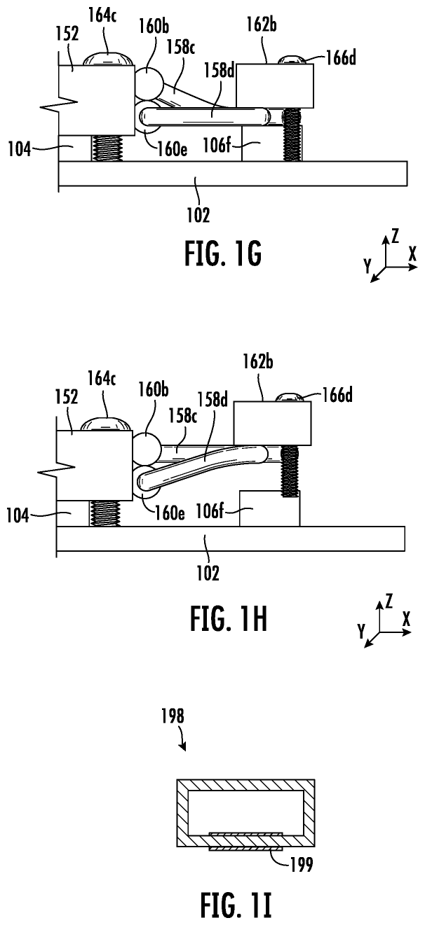

FIG. 1A is a top view of an electronic module 100, in accordance with an embodiment of the invention. As shown in FIG. 1A, the electronic module 100 may include a substrate 102, a main die 104 positioned on the central portion of the surface of the substrate 102, and a plurality of optical modules 106a-1061 (e.g., mid-board optical modules (MBOMs)). In some embodiments, the substrate 102 may include electrical traces, not shown (e.g., through a thickness the substrate 102), and the main die 104 may be in electrical communication with the electrical traces. The main die 104 may have a top die surface (e.g., an upper surface, as shown) opposite a die attachment surface (e.g., a bottom surface, not shown in FIG. 1A) on the substrate 102 and may include a heat sink defining the top die surface.

As shown in FIG. 1A, the plurality of optical modules 106a-1061 may be positioned on a peripheral portion of the surface of the substrate 102 (e.g., outside of a component-free zone around the main die 104, between outer edges of the substrate 102 and the main die 104 and/or the component-free zone, and/or the like). In some embodiments, the optical modules 106a-1061 may include one or more optical devices, input/output connections, and a power connection. For example, the optical devices may include photonic integrated circuits (PICs) and/or other optical communication devices (e.g., lasers, laser modulators, laser drivers, photo detectors (PD), amplifiers (TIA), and/or the like).

In some embodiments, each of the plurality of optical modules 106a-1061 may be in electrical communication with the main die 104. For example, each of the plurality of optical modules 106a-1061 may be connected to the substrate 102 and/or in electrical communication with one or more of the electrical traces through the substrate 102 via a connector, socket, ball grid array, and/or the like. In some embodiments, each of the plurality of optical modules 106a-1061 may have a top module surface (e.g., an upper surface) opposite a module attachment surface (e.g., a bottom surface) on the substrate 102 and may include a heat sink defining the top module surface.

As shown in FIG. 1A, the electronic module 100 may include an optical connector 108, and the optical module 106c may be in optical communication with one or more optical devices (e.g., one or more other electronic modules, switches, and/or the like) via optical fibers connected to the optical connector 108. For example, one or more optical fiber cables may be connected to the optical connector 108 and may connect to another optical device such that the optical module 106c is in optical communication with the other optical device. As will be appreciated by those of ordinary skill in the art in view of this disclosure, although only one optical connector 108 is shown in FIG. 1A, the electronic module 100 may include additional optical connectors similar to the optical connector 108 for one or more of the other optical modules 106a, 106b, 106d-1061, and/or the like.

As shown in FIG. 1A, the substrate 102 of the electronic module 100 may define a plurality of first fastener holes 114a-114d. As will be described with respect to FIG. 1B, each of the first fastener holes 114a-114d may be configured to receive a fastener for securing a cold plate of a cooling system to the substrate 102 proximate an upper surface of the main die 104.

As also shown in FIG. 1A, the substrate 102 of the electronic module 100 may define a plurality of second fastener holes 116a-116h. As will be described with respect to FIG. 1B, each of the second fastener holes 116a-116h may be configured to receive a fastener for securing a satellite plate of a cooling system to the substrate 102 proximate upper surfaces of the optical modules 106a-1061.

FIG. 1B is a top view of a cooling system 150 that is configured to cooperate with the electronic module 100 of FIG. 1A, in accordance with an embodiment of the invention. FIGS. 1G and 1H are side views of portions of the electronic module 100 of FIG. 1A and the cooling system 150 of FIG. 1B. As shown in FIG. 1B, the cooling system 150 may include a cold plate 152 defining a fluid inlet 154 for receiving a cooling fluid and a fluid outlet 156 for releasing a cooling fluid. As also shown in FIG. 1B, the cooling system 150 may include a plurality of cooling conduits 158a-158h, a plurality of coupling blocks 160a-160d, a plurality of satellite plates 162a-162d, a plurality of first fasteners 164a-164d (e.g., screws, bolts, pins, and/or the like), and a plurality of second fasteners 166a-166h (e.g., screws, bolts, pins, and/or the like).

In some embodiments, each of the first fasteners 164a-164d may be configured to releasably secure the cold plate 152 to the substrate 102 of the electronic module 100 by engaging one of the first fastener holes 114a-114d (shown in FIG. 1A). For example, each of the first fasteners 164a-164d may include a bolt and a nut, where the bolts are configured to pass through the cold plate 152 and one of the first fastener holes 114a-114d, and the nuts are configured to thread onto the bolts proximate a bottom surface of the substrate 102.

In some embodiments, each of the second fasteners 166a-166h may be configured to releasably secure one of the satellite plates 162a-162d to the substrate 102 of the electronic module 100 by engaging one of the second fastener holes 116a-116h (shown in FIG. 1A). For example, each of the second fasteners 166a-166h may include a bolt and a nut, where the bolts are configured to pass through one of the satellite plates 162a-162d and one of the second fastener holes 116a-116h and the nuts are configured to thread onto the bolts proximate a bottom surface of the substrate 102. In this regard, the satellite plates 162a-162d may be satellite supports configured to secure the cooling conduits 158a-158h and/or the optical modules 106a-1061 in place with respect to the substrate 102.

When the cooling system 150 is secured to the electronic module 100, the cold plate 152 may be thermally coupled to the upper surface of the main die 104 (e.g., a top die surface, which may include and/or be defined by a heat sink). The main die 104 may be actively cooled by the cold plate 152 due to the cooling fluid passing through the fluid inlet 154 and the fluid outlet 156. In this way, the cold plate 152 may receive heat from the upper surface of the main die 104, the cooling fluid may absorb the heat, and the warmed cooling fluid may pass through the fluid outlet 156.

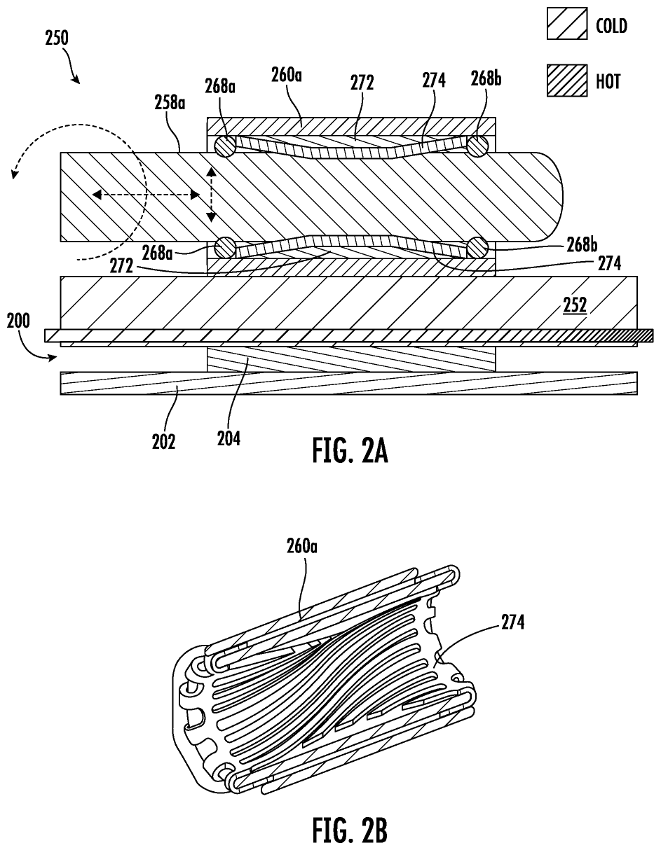

In some embodiments, each of the cooling conduits 158a-158h may be heat pipes configured such that, when the cooling system 150 is secured to the electronic module 100, portions of the heat pipes are positioned between upper surfaces (e.g., top module surfaces defined by heat sinks) of the optical modules 106a-1061 and the satellite plates 162a-162d as shown in FIG. 1B by the portions of the cooling conduits 158a-158h shown via dashed lines. As also shown in FIG. 1B, the cooling conduits 158a-158h may be thermally coupled to the cold plate 152 by the coupling blocks 160a-160d. Although not shown in FIG. 1B due to the viewing angle, each of the cooling conduits 158a-158h may be thermally coupled to the cold plate 152 by a respective coupling block. In some embodiments, one or more of the coupling blocks 160a-160d may be similar to the coupling block shown and described herein with respect to FIGS. 2A and 2B.

As will be appreciated by those of ordinary skill in the art in view of this disclosure, each heat pipe may include a heat transfer device that uses phase transition to transfer heat between two surfaces. For example, each heat pipe may include a liquid (e.g., water) positioned within a thermally conductive outer shell (e.g., a metal outer shell) having a porous structure on its interior surface. When the liquid contacts the outer shell in the portions adjacent the optical modules 106a-1061, the liquid absorbs the heat and transitions to a vapor. The vapor travels through the interior of the outer shell toward the coupling blocks 160a-160d. Because the portions of the heat pipes adjacent the coupling blocks 160a-160d are cool (e.g., due to being thermally coupled to the cold plate 152), the vapor releases the heat and condenses into a liquid. The porous structure then returns the condensed liquid to the portions adjacent the optical modules 106a-1061 via capillary action (e.g., wicking). The liquid then absorbs the heat, and the process is repeated. As will be appreciated by those of ordinary skill in the art in view of this disclosure, the heat pipes may use another process to transfer heat between the optical modules 106a-1061 and the coupling blocks 160a-160d in some embodiments.

In this way, the cooling conduits 158a-158h, in the form of heat pipes, may passively cool the optical modules 106a-1061 by receiving heat from upper surfaces of the optical modules 106a-1061 and releasing the heat through the coupling blocks 160a-160d to the cold plate 152. The heat pipes may reduce a likelihood of the cooling system 150 forming leaks because the heat pipes use a closed system to cool the optical modules 106a-1061.

In some embodiments, the coupling blocks 160a-160d and the cooling conduits 158a-158h may be configured to permit rotation of the cooling conduits 158a-158h between a cooling position in which the cooling conduits 158a-158h are proximate the optical modules 106a-1061 and an access position in which the cooling conduits 158a-158h are spaced from the optical modules 106a-1061. For example, the cooling conduits 158a-158h as shown in FIG. 1B are in the cooling position such that, when the cooling system 150 is positioned on the electronic module 100, the cooling conduits 158a-158h are proximate upper surfaces of the optical modules 106a-1061. In the orientations shown in FIGS. 1A and 1B, the coupling blocks 160a-160d and the cooling conduits 158a-158h may be configured to permit rotation of the cooling conduits 158a-158h upward (e.g., in a z-direction) and away from the substrate 102 and/or the optical modules 106a-1061 into an access position such that the optical modules 106a-1061 may be accessed without removing the cold plate 152 from the main die 104.

FIG. 1G depicts a side view of a portion of the electronic module 100 and the cooling system 150 while the cooling conduits 158c and 158d are in the cooling position. The portion of the electronic module 100 shown in FIG. 1G includes a portion of the substrate 102, a portion of the main die 104, and the optical modules 106d, 106e, and 106f, although the optical modules 106d and 106e are not visible in FIG. 1G due to the viewing angle. The portion of the cooling system 150 shown in FIG. 1G includes a portion of the cold plate 152, the cooling conduits 158c and 158d, the coupling block 160b, a coupling block 160e, and the satellite plate 162b. As shown in FIG. 1G, when the cooling system 150 is positioned on the electronic module 100, the cooling conduits 158c and 158d are proximate upper surfaces of the optical modules 106d-106f in the cooling position.

When the cooling system 150 is positioned on and secured to the electronic module 100 and a technician requires access to the optical module 106f (e.g., to service, repair, replace, and/or the like the optical module 106f), the second fasteners 166c and 166d may be released from the second fastener holes 116c and 116d, respectively. After releasing the second fasteners 166c and 166d, the satellite plate 162b may be lifted away from the substrate 102, and the coupling blocks 160b and 160e and the cooling conduits 158c and 158d may permit rotation of the cooling conduits 158c and 158d upward and away from the upper surface of the optical module 106f. For example, FIG. 1H depicts a side view of the portion of the electronic module 100 and the portion of the cooling system 150 of FIG. 1G while the cooling conduits 158c and 158d are in the access position.

Continuing with this example, after the technician no longer requires access to the optical module 106f, the coupling blocks 160b and 160e and the cooling conduits 158c and 158d may permit rotation of the cooling conduits 158c and 158d downward and toward the upper surface of the optical module 106f. The satellite plate 162b may be repositioned over the cooling conduits 158c and 158d, and the second fasteners 166c and 166d may be re-attached to the substrate 102 via the second fastener holes 116c and 116d, respectively.

In this way, removal of the entire cooling system 150 is not required to access the optical modules 106a-1061. Furthermore, accurate and precise positioning of (i) the cold plate 152 with respect to the main die 104 and (ii) the cooling conduits 158a-158h with respect to the optical modules 106a-1061 may be maintained before and after accessing one or more of the optical modules 106a-1061.

Although FIGS. 1G and 1H depict the coupling blocks 160b and 160e as being vertically offset from each other in the z-direction, the coupling blocks 160b and 160e, as well as other coupling bocks of the cooling system 150, may be vertically aligned with each other in the z-direction, in some embodiments. Additionally, or alternatively, the cooling conduits 158c and 158d are depicted in FIGS. 1G and 1H as being flexible and/or bendable, but the cooling conduits 158c and 158d, as well as the other cooling conduits of the cooling system 150, may be substantially rigid, in some embodiments. For example, the coupling blocks 160b and 160e and the cooling conduits 158c and 158d may be configured such that their interaction provides enough rotation of the cooling conduits 158c and 158d within the respective coupling blocks 160b and 160e to permit access to the optical modules 106d-106f.

FIGS. 1C-1F are top views of portions of a cooling system, in accordance with embodiments of the invention. In particular, FIGS. 1C-1F depict cooling conduits 180-188 that may correspond to one or more of the cooling conduits 158a-158h of the cooling system 150 of FIG. 1B but in different configurations. FIGS. 1C-1F also depict coupling blocks 190-196 that may correspond to one or more of the coupling blocks 160a-160d of the cooling system 150 of FIG. 1B.

As shown in FIG. 1C, the cooling conduit 180 may include a base portion 180a extending through and operatively coupled to the coupling block 190. The cooling conduit 180 may further include a first lateral portion 180b, a first extension portion 180c, a second lateral portion 180d, and a second extension portion 180e. As shown in FIG. 1C, the first lateral portion 180b may extend from the base portion 180a (e.g., at an angle, such as an approximately 90-degree angle), and the second lateral portion 180d may extend from the base portion 180a (e.g., at an angle, such as an approximately 90-degree angle) in substantially the same direction as the first lateral portion 180b.

As also shown in FIG. 1C, the first lateral portion 180b may connect the first extension portion 180c to the base portion 180a, and the second lateral portion 180d may connect the second extension portion 180e to the base portion 180a. In some embodiments, and as shown in FIG. 1C, the first extension portion 180c may extend from the first lateral portion 180b at an angle of approximately 90 degrees and toward the second extension portion 180e, and the second extension portion 180e may extend from the second lateral portion 180d at an angle of approximately 90 degrees and toward the first extension portion 180c. In this regard, the first extension portion 180c and the second extension portion 180e may be configured to thermally couple the cooling conduit 180 to one or more optical modules, such as the optical modules 106a-1061 of FIG. 1A.

As shown in FIG. 1D, the cooling conduit 182 may include an extension portion 182a, a first lateral portion 180b, a first base portion 182c, a second lateral portion 180d, and a second base portion 182e. Each of the first base portion 182c and the second base portion 182e may partially extend through and be operatively coupled to the coupling block 192. As shown in FIG. 1D, the first lateral portion 182b may extend from the first base portion 182c (e.g., at an angle, such as an approximately 90-degree angle), and the second lateral portion 182d may extend from the second base portion 182e (e.g., at an angle, such as an approximately 90-degree angle) in substantially the same direction as the first lateral portion 182b.

As also shown in FIG. 1D, the first lateral portion 182b may connect the extension portion 182a to the first base portion 182c, and the second lateral portion 182d may connect the extension portion 182a to the second base portion 182e. In some embodiments, and as shown in FIG. 1D, the extension portion 182a may extend from the first lateral portion 182b at an angle of approximately 90 degrees to the second lateral portion 182d, and the extension portion 182a may extend from the second lateral portion 182d at an angle of approximately 90 degrees to the first lateral portion 182b. In this regard, the extension portion 182a may be configured to thermally couple the cooling conduit 182 to one or more optical modules, such as the optical modules 106a-1061 of FIG. 1A.

As shown in FIG. 1E, the cooling conduits 184 and 186 may each include a base portion 184a and 186a, respectively, partially extending through and operatively coupled to the coupling block 194 (e.g., on opposite sides of the coupling block 194). The cooling conduits 184 and 186 may each respectively include a lateral portion 184b and 186b and an extension portion 184c and 186c. As shown in FIG. 1E, the lateral portions 184b and 186b may each extend from the base portions 184a and 186a, respectively, (e.g., at an angle, such as an approximately 90-degree angle) and in substantially the same direction.

As also shown in FIG. 1E, the lateral portions 184b and 186b may respectively connect the extension portions 184c and 186c to the base portions 184a and 186a, respectively. In some embodiments, and as shown in FIG. 1E, the extension portion 184c may extend from the lateral portion 184b at an angle of approximately 90 degrees and toward the extension portion 186c, and the extension portion 186c may extend from the lateral portion 186b at an angle of approximately 90 degrees and toward the extension portion 184c. In this regard, the extension portions 184c and 186c may be configured to thermally couple the cooling conduits 184 and 186 to one or more optical modules, such as the optical modules 106a-1061 of FIG. 1A.

As shown in FIG. 1F, the cooling conduit 188 may include a base portion 188a extending through and operatively coupled to the coupling block 196. The cooling conduit 188 may further include a lateral portion 188b and an extension portion 188c. As shown in FIG. 1F, the lateral portion 188b may extend from the base portion 188a (e.g., at an angle, such as an approximately 90-degree angle).

As also shown in FIG. 1F, the lateral portion 188b may connect the extension portion 188c to the base portion 188a. In some embodiments, and as shown in FIG. 1F, the extension portion 188c may extend from the lateral portion 188b at an angle of approximately 90 degrees and substantially parallel to the base portion 188a. In this regard, the extension portion 188c may be configured to thermally couple the cooling conduit 188 to one or more optical modules, such as the optical modules 106a-1061 of FIG. 1A.

In some embodiments, one or more of the cooling conduits of the cooling system 150 may be a closed-loop thermosiphon. FIG. 1I is a top view of a portion of a cooling system, in accordance with such an embodiment of the invention. As shown in FIG. 1I, a cooling conduit 198 may form a closed-loop thermosiphon extending through and operatively coupled to a coupling block 199. As will be appreciated by those of ordinary skill in the art in view of this disclosure, a closed-loop thermosiphon uses natural convection and passive heat exchange to circulate a fluid (e.g., without a mechanical pump). In such embodiments, the cooling conduit may include a fluid that freely flows within the cooling conduit, and a portion of the cooling conduit may be thermally coupled to one or more optical modules. The fluid within the portion of the cooling conduit thermally coupled to the one or more optical modules may absorb heat from the one or more optical modules, thereby creating a difference in density of the fluid across the loop of the cooling conduit. The cooling conduit, the coupling block thermally coupling the cooling conduit to the cold plate, and/or the cold plate may be configured such that the difference in density causes the warm fluid to flow away from the one or more optical modules and be replaced by cooler fluid. In this way, the heat may be absorbed by the cooling conduit and transferred away from the one or more optical modules.

As will be appreciated by those of ordinary skill in the art in view of this disclosure, FIGS. 1A-1I depict a simplified and/or representative design for an electronic module, a cooling system, cooling conduits, coupling blocks, and satellite plates, in accordance with embodiments of the invention. For example, the electronic module 100 may include fewer optical modules (e.g., eight, seven, six, five, four, three, two, or even one optical module), more optical modules (e.g., ten, eleven, twelve, or more optical modules), and/or differently sized, shaped, and/or positioned optical modules, and the cooling system 150 may have a corresponding number of cooling conduits, coupling blocks, and/or satellite plates to sufficiently cool the optical modules to maintain an appropriate operating temperature. In some embodiments, the cooling system 150 may include fewer cooling conduits, coupling blocks, and/or satellite plates; more cooling conduits, coupling blocks, and/or satellite plates; and/or differently sized, shaped, and/or positioned cooling conduits, coupling blocks, and/or satellite plates. For example, the cooling conduits may have differently sized portions, portions extending from each other at different angles, and/or the like as compared to those shown in FIGS. 1B-1I. Additionally, or alternatively, the substrate 102 and/or the main die 104 may have a different size and/or shape as compared to that shown in FIG. 1A.

FIG. 2A is a cross-sectional side view of a portion of an electronic module 200 as engaged with a portion of a cooling system 250, in accordance with an embodiment of the invention. FIG. 2B is a cross-sectional perspective view of a coupling block 260a of the cooling system 250 of FIG. 2A, in accordance with an embodiment of the invention. In some embodiments, the electronic module 200 may be similar to the electronic module 100 as shown and described herein with respect to FIG. 1A. For example, and as shown in FIG. 2A, the electronic module 200 may include a substrate 202 and a main die 204 positioned on the central portion of a surface of the substrate 202. Although not shown in FIG. 2A, the electronic module 200 may further include a plurality of optical modules positioned on a peripheral portion of the surface of the substrate 202 as well as the other components of the electronic module 100 as shown and described herein with respect to FIG. 1A.

Additionally, or alternatively, the cooling system 250 may be similar to the cooling system 150 as shown and described herein with respect to FIGS. 1B-1I. For example, and as shown in FIG. 2A, the cooling system 250 may include a cold plate 252, a cooling conduit 258a (e.g., a heat pipe, a thermosiphon, and/or the like), and a coupling block 260a. As also shown in FIG. 2A, the cooling conduit 258a may be thermally coupled to the cold plate 252 by the coupling block 260a. Although not shown in FIG. 2A, the cooling system 250 may further include additional cooling conduits, additional coupling blocks, and/or satellite plates as well as the other components of the cooling system 150 as shown and described herein with respect to FIGS. 1B-1I.

As shown in FIG. 2A, the coupling block 260a may include an opening for receiving the cooling conduit 258a, and a pair of O-ring seals 268a and 268b disposed between the inner surface of the opening and the cooling conduit 258a. For example, and as shown in FIG. 2A, the O-ring seals 268a and 268b may be positioned at opposite ends of the opening in the coupling block 260a. As further shown in FIG. 2A, the coupling block 260a may include a thermal transfer medium 272 (e.g., liquid metal, thermal grease, and/or the like) disposed between the O-ring seals 268a and 268b and between the inner surface and the cooling conduit 258a to enhance the thermal coupling between the coupling block 260a and the cooling conduit 258a. In some embodiments, the O-ring seals 268a and 268b may prevent the thermal transfer medium 272 from leaking out of the coupling block 260a and/or center the cooling conduit 258a within the coupling block 260a.

Although two O-ring seals 268a and 268b are shown in the embodiment of FIG. 2A, the coupling block 260a may include fewer O-ring seals or more O-ring seals in some embodiments. For example, one end of the opening in the coupling block 260a may be fully sealed (e.g., such that an end of the cooling conduit is positioned within the coupling block), and the other end of the opening may include on O-ring seal.

As shown in FIGS. 2A and 2B, the coupling block 260a may include an interface contact 274 disposed between the O-ring seals 268a and 268b and between an outer surface of the cooling conduit 258a and the thermal transfer medium 272. In some embodiments, the interface contact 274 may deform when the cooling conduit 258a is positioned in the coupling block 260a and secure the cooling conduit 258a within the coupling block 260a. Additionally, or alternatively, the interface contact 274 may center the cooling conduit 258a within the coupling block 260a.

As shown in FIGS. 2A and 2B, the coupling block 260a may include a pin-and-socket structure configured to receive and rotatably support the cooling conduit 258a (e.g., a heat pipe, a thermosiphon, and/or the like). For example, the coupling block 260a may include a pin-and-socket structure (e.g., a Radsok® electrical connection, a Molex® Sentrality pin and socket interconnect system, and/or the like) filled with the thermal transfer medium 272 and the O-ring seals 268a and 268b. By rotatably supporting the cooling conduit 258a in this manner, the coupling block 260a and the cooling conduit 258a may permit rotation of the cooling conduit 258a upward and away from an upper surface of an optical module of the electronic module 200 as further described herein with respect to FIGS. 1A-1H.

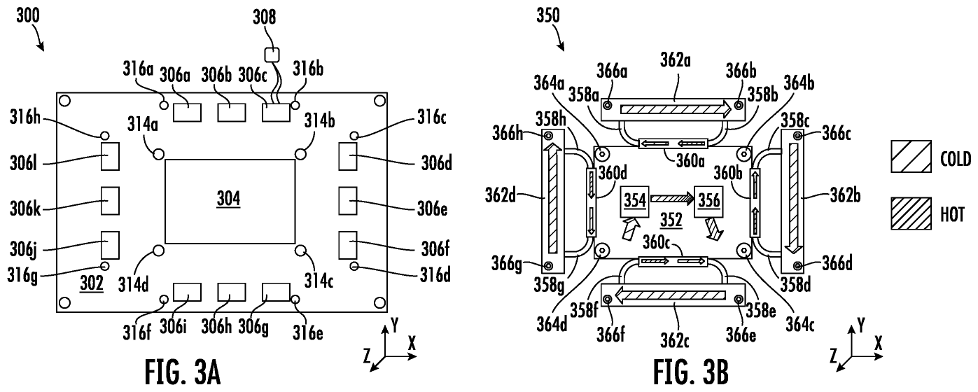

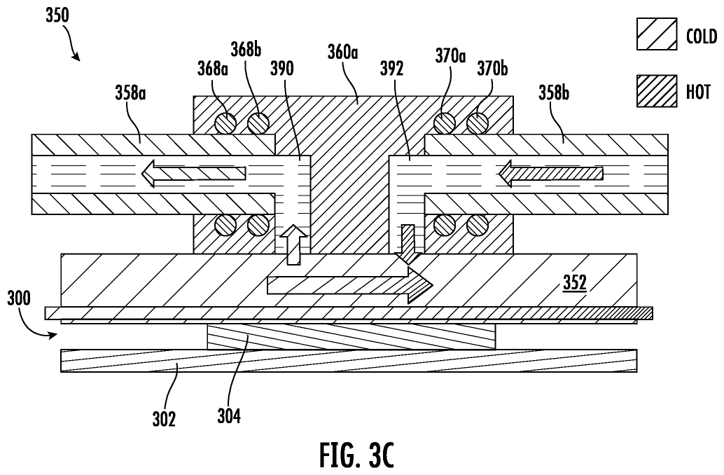

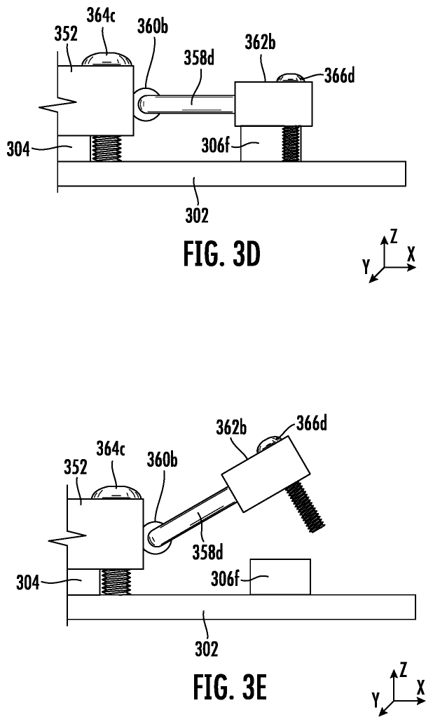

FIG. 3A is a top view of an electronic module 300, in accordance with an embodiment of the invention. As shown in FIG. 3A, the electronic module 300 may include a substrate 302, a main die 304, a plurality of optical modules 306a-3061, an optical connector 308, a plurality of first fastener holes 314a-314d, and a plurality of second fastener holes 316a-316h. The substrate 302, the main die 304, the plurality of optical modules 306a-3061, the optical connector 308, the plurality of first fastener holes 314a-314d, and the plurality of second fastener holes 316a-316h may be similar to the substrate 102, the main die 104, the plurality of optical modules 106a-1061, the optical connector 108, the plurality of first fastener holes 114a-114d, and the plurality of second fastener holes 116a-116h shown and described herein with respect to FIG. 1A.

FIG. 3B is a top view of a cooling system 350 that is configured to cooperate with the electronic module 300 of FIG. 3A, in accordance with an embodiment of the invention. FIGS. 3D and 3E are side views of portions of the electronic module 300 of FIG. 3A and the cooling system 350 of FIG. 3B. As shown in FIG. 3B, the cooling system 350 may include a cold plate 352 defining a fluid inlet 354 for receiving a cooling fluid and a fluid outlet 356 for releasing a cooling fluid. As also shown in FIG. 3B, the cooling system 350 may include a plurality of cooling conduits 358a-358h, a plurality of coupling blocks 360a-360d, a plurality of satellite plates 362a-1362d, a plurality of first fasteners 364a-364d (e.g., screws, bolts, pins, and/or the like), and a plurality of second fasteners 366a-366h (e.g., screws, bolts, pins, and/or the like).

In some embodiments, each of the first fasteners 364a-364d may be configured to releasably secure the cold plate 352 to the substrate 302 of the electronic module 300 by engaging one of the first fastener holes 314a-314d. For example, each of the first fasteners 364a-364d may include a bolt and a nut, where the bolts are configured to pass through the cold plate 352 and one of the first fastener holes 314a-314d and the nuts are configured to thread onto the bolts proximate a bottom surface of the substrate 302.

In some embodiments, each of the second fasteners 366a-366h may be configured to releasably secure one of the satellite plates 362a-362d to the substrate 302 of the electronic module 300 by engaging one of the second fastener holes 316a-316h. For example, each of the second fasteners 366a-366h may include a bolt and a nut, where the bolts are configured to pass through one of the satellite plates 362a-362d and one of the second fastener holes 316a-316h and the nuts are configured to thread onto the bolts proximate a bottom surface of the substrate 302. In this regard, the satellite plates 362a-362d may be configured to secure the cooling conduits 358a-358h and/or the optical modules 306a-3061 in place with respect to the substrate 302.

When the cooling system 350 is secured to the electronic module 300, the cold plate 352 may be thermally coupled to the upper surface of the main die 304 (e.g., a top die surface defined by a heat sink). The main die 304 may be actively cooled by the cold plate 352 due to the cooling fluid passing through the fluid inlet 354 and the fluid outlet 356. In this way, the cold plate 352 may receive heat from the upper surface of the main die 304, the cooling fluid may absorb the heat, and the warmed cooling fluid may pass through the fluid outlet 356.

FIG. 3C is a cross-sectional side view of a portion of the electronic module 300 of FIG. 3A as engaged with a portion of the cooling system 350 of FIG. 3B. In particular, FIG. 3C is a cross-sectional side view through the coupling block 360a and the cooling conduits 358a and 358b when the cooling system 350 is secured to the electronic module 300. As shown in FIG. 3C, the coupling block 360a may include a first pair of O-ring seals 368a and 368b, a second pair of O-ring seals 370a and 370b, a first port 390, and a second port 392. In some embodiments, each of the coupling blocks 360a-360d may include the components of the coupling block 360a depicted in FIG. 3C.

Additionally, or alternatively, each of the cooling conduits 358a-358h may be a fluid hose (e.g., flexible fluid hoses, rigid fluid hoses, fluid pipes, and/or the like), each of the satellite plates 362a-362d may be satellite cold plates, and each of the coupling blocks 360a-360d may be fluid coupling blocks. Each satellite cold plate may define a passage extending through the satellite cold plate (e.g., as shown by the arrows in FIG. 3B), and a pair of fluid hoses may be in fluid communication with either end of the satellite cold plate. The fluid coupling blocks may be configured to provide a portion of the cooling fluid from the fluid inlet 354 of the cold plate 352 to one fluid hose and to provide the portion of the cooling fluid from another fluid hose to the fluid outlet 356 of the cold plate 352. The cold plate 352 may be configured to provide cooling fluid from the fluid inlet 354 to one port in the fluid coupling blocks, receive heated cooling fluid from another port in the fluid coupling blocks, and release the heated cooling fluid through the fluid outlet 356.

For example, and as shown in FIG. 3C, the coupling block 360a may be a fluid coupling block configured to provide cooling fluid from the cold plate 352 to the cooling conduit 358a via the first port 390. The cooling conduit 358a may be a fluid hose in fluid communication with a first end of a passage extending through the satellite plate 362a (e.g., a satellite cold plate) and may be configured to provide the cooling fluid from the coupling block 360a to the passage extending through the satellite plate 362a, as shown in FIG. 3B. The cooling conduit 358b may be in fluid communication with a second end of the passage extending through the satellite plate 362a and may be configured to provide the cooling fluid from the other end of the passage extending through the satellite plate 362a to the second port 392, as shown in FIG. 3C. The coupling block 360a may be configured to provide the cooling fluid from the cooling conduit 358b to the cold plate 352.

In some embodiments, the cold plate 352, the coupling blocks 360a-360d, the cooling conduits 358a-358h, and the satellite plates 362a-362d may be configured such that, when the cooling system 350 is secured to the electronic module 300, the satellite plates 362a-362d are positioned on upper surfaces (e.g., top module surfaces defined by heat sinks) of the optical modules 306a-3061. In this way, the coupling blocks 360a-360d, the cooling conduits 358a-358h, and the satellite plates 362a-362d may actively cool the optical modules 306a-3061 by receiving heat from upper surfaces of the optical modules 306a-3061 via the cooling fluid flowing through the satellite plates 362a-362d, transferring the heated cooling fluid through the coupling blocks 360a-360d to the cold plate 352, and releasing the heated cooling fluid through the fluid outlet 356.

In some embodiments, the coupling blocks 360a-360d, the cooling conduits 358a-358h, and the satellite plates 362a-362d may be configured to permit rotation of the cooling conduits 358a-358h and the satellite plates 362a-362d between a cooling position in which the satellite plates 362a-362d are proximate the optical modules 306a-3061 and an access position in which the satellite plates 362a-362d are spaced from the optical modules 306a-3061. For example, the cooling conduits 358a-358h and the satellite plates 362a-362d as shown in FIG. 3B are in the cooling position such that, when the cooling system 350 is positioned on the electronic module 300, the satellite plates 362a-362d are proximate upper surfaces of the optical modules 106a-1061. In the orientations shown in FIGS. 3A and 3B, the coupling blocks 360a-360d, the cooling conduits 358a-358h, and the satellite plates 362a-362d may be configured to permit rotation of the cooling conduits 358a-358h and the satellite plates 362a-362d upward (e.g., in a z-direction) and away from the substrate 302 and/or the optical modules 306a-3061 into an access position such that the optical modules 306a-3061 may be accessed without removing the cold plate 352 from the main die 304.

In this regard, O-ring seals in the coupling blocks (e.g., similar to the first pair of O-ring seals 368a and 368b and the second pair of O-ring seals 370a and 370b shown in FIG. 3C) may be configured to permit rotation of the cooling conduits 358a-358h while maintaining a fluid-tight seal. For example, and as shown in FIG. 3C with respect to the coupling block 360a, the coupling block 360a may include openings for receiving the cooling conduits 358a and 358b, the first pair of O-ring seals 368a and 368b may be disposed between the inner surface of one opening and the cooling conduit 358a, and the second pair of O-ring seals 370a and 370b may be disposed between the inner surface of the other opening and the cooling conduit 358b. In some embodiments, the first pair of O-ring seals 368a and 368b and the second pair of O-ring seals 370a and 370b may prevent the cooling fluid from leaking out of the coupling block 360a and/or center the cooling conduits 358a and 358b within the coupling block 360a.

Although pairs of O-ring seals are shown in the embodiment of FIG. 3C, the coupling block 360a may include fewer O-ring seals or more O-ring seals in some embodiments. For example, only one O-ring seal may be used in each opening of the coupling block 360a. As another example, more than two O-ring seals may be used in each opening of the coupling block 360a.

As previously described, the coupling blocks 360a-360d, the cooling conduits 358a-358h, and the satellite plates 362a-362d may be configured to permit rotation of the cooling conduits 358a-358h and the satellite plates 362a-362d between a cooling position and an access position, in some embodiments. FIG. 3D depicts a side view of a portion of the electronic module 300 and the cooling system 350 while the cooling conduits 358c and 358d and the satellite plate 362b are in the cooling position. The portion of the electronic module 300 shown in FIG. 3D includes a portion of the substrate 302, a portion of the main die 304, and the optical modules 306d, 306e, and 306f, although the optical modules 306d and 306e are not visible in FIG. 3D due to the viewing angle. The portion of the cooling system 350 shown in FIG. 3D includes a portion of the cold plate 352, the cooling conduits 358c and 358d (although the cooling conduit 358c is not visible in FIG. 3D due to the viewing angle), the coupling block 360b, and the satellite plate 362b. As shown in FIG. 3D, when the cooling system 350 is positioned on the electronic module 300, the cooling conduits 358c and 358d and the satellite plate 362b are proximate upper surfaces of the optical modules 306d-306f in the cooling position.

When the cooling system 350 is positioned on and secured to the electronic module 300 and a technician requires access to the optical module 306f (e.g., to service, repair, replace, and/or perform other functions on the optical module 306f), the second fasteners 366c and 366d may be released from the second fastener holes 316c and 316d, respectively. After releasing the second fasteners 366c and 366d, the satellite plate 362b may be lifted away from the substrate 302, and the coupling block 360b and the cooling conduits 358c and 358d may permit rotation of the cooling conduits 358c and 358d and the satellite plate 362b upward and away from the upper surface of the optical module 306f. For example, FIG. 3E depicts a side view of the portion of the electronic module 300 and the portion of the cooling system 350 of FIG. 3D while the cooling conduits 358c and 358d and the satellite plate 362b are in the access position.

Continuing with this example, after the technician no longer requires access to the optical module 306f, the coupling block 360b and the cooling conduits 358c and 358d may permit rotation of the conduits 358c and 358d and the satellite plate 362b downward and toward the upper surface of the optical module 306f. The second fasteners 366c and 366d may be re-attached to the substrate 302 via the second fastener holes 316c and 316d, respectively. In this way, removal of the entire cooling system 350 is not required to access the optical modules 306a-3061. Furthermore, accurate and precise positioning of (i) the cold plate 352 with respect to the main die 304 and (ii) the satellite plates 362a-362d with respect to the optical modules 306a-3061 may be maintained before and after accessing one or more of the optical modules 306a-3061.

As will be appreciated by those of ordinary skill in the art in view of this disclosure, FIGS. 3A-3E depict a simplified and/or representative design for an electronic module, a cooling system, cooling conduits, coupling blocks, and satellite plates in accordance with embodiments of the invention. For example, the electronic module 300 may include fewer optical modules (e.g., eight, seven, six, five, four, three, two, or even one optical module), more optical modules (e.g., ten, eleven, twelve, or more optical modules), and/or differently sized, shaped, and/or positioned optical modules, and the cooling system 350 may have an appropriate number of cooling conduits, coupling blocks, and/or satellite plates to sufficiently cool the optical modules to maintain an appropriate operating temperature. In some embodiments, the cooling system 350 may include fewer cooling conduits, coupling blocks, and/or satellite plates; more cooling conduits, coupling blocks, and/or satellite plates; and/or differently sized, shaped, and/or positioned cooling conduits, coupling blocks, and/or satellite plates. For example, the cooling conduits may have differently sized portions, portions extending from each other at different angles, and/or the like as compared to those shown in FIGS. 3A-3E. Additionally, or alternatively, the substrate 302 and/or the main die 304 may have a different size and/or shape as compared to that shown in FIG. 3A.

FIGS. 1A-1I and 2A-2B present embodiments of cooling systems that passively cool optical modules (e.g., using heat pipes, thermosiphons, and/or the like), and FIGS. 3A-3E present embodiments of cooling systems that actively cool optical modules (e.g., using fluid hoses). As will be appreciated by those of ordinary skill in the art in view of this disclosure, some embodiments of the present invention may include cooling systems that both passively cool optical modules and actively cool optical modules. For example, a cooling system may use both heat pipes and fluid hoses to cool optical modules. As another example, a cooling system may use heat pipes to cool one or more optical modules and fluid hoses to cool one or more other optical modules on the same substrate. In such embodiments, the cooling system may be configured to account for differences in heat produced by different optical modules of an electronic module.

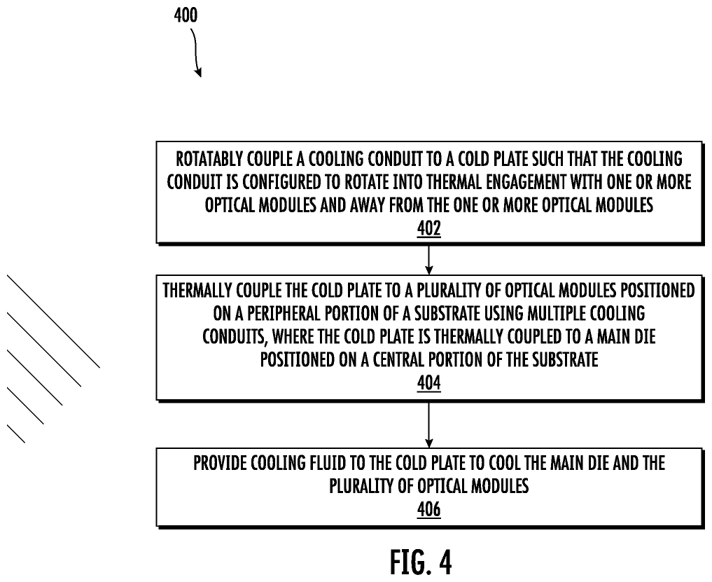

FIG. 4 is a flowchart illustrating a method 400 of cooling components of an electronic module, in accordance with an embodiment of the invention. In some embodiments, the electronic module may be similar to one or more of the electronic modules described herein, such as the electronic module 100 of FIG. 1A, the electronic module 200 of FIG. 2A, and/or the electronic module 300 of FIGS. 3A and 3C.

As shown in block 402, the method 400 may include rotatably coupling a cooling conduit to a cold plate such that the cooling conduit is configured to rotate into thermal engagement with one or more optical modules and away from the one or more optical modules. For example, the method 400 may include using a coupling block similar to the coupling blocks described herein with respect to FIGS. 1B-1I, 2A, 2B, 3B, 3C, 3D, and/or 3E to rotatably couple a cooling conduit to a cold plate.

As shown in block 404, the method 400 may include thermally coupling the cold plate to a plurality of optical modules positioned on a peripheral portion of a substrate using multiple cooling conduits, where the cold plate is thermally coupled to a main die positioned on a central portion of the substrate. The plurality of optical modules may include the one or more optical modules thermally engaged by the rotatably-coupled cooling conduit, and the multiple cooling conduits may include the rotatably-coupled cooling conduit. For example, the method 400 may include thermally coupling a cold plate similar to the cold plates described herein with respect to FIGS. 1B, 1G, 1H, 2A, 3B, 3C, 3D, and/or 3E to a plurality of optical modules using cooling conduits, coupling blocks, and/or satellite plates in a manner similar to that described herein with respect to FIGS. 1A-1I, 2A, 2B, and/or 3A-3E.

In some embodiments, each cooling conduit may be thermally coupled to the cold plate by a respective coupling block positioned on the cold plate. For example, the cooling conduits may be heat pipes and/or thermosiphons, and the coupling blocks may be similar to the coupling blocks described herein with respect to FIGS. 1B-1I, 2A, and/or 2B. As another example, the cooling conduits may be fluid hoses, and the coupling blocks may be similar to the coupling blocks described herein with respect to FIGS. 3B, 3C, 3D, and/or 3E.

As shown in block 406, the method 400 may include providing cooling fluid to the cold plate to cool the main die and the plurality of optical modules. For example, the method 400 may include providing cooling fluid to a fluid inlet of the cold plate, which may cool the main die as well as the plurality of optical modules using the multiple cooling conduits. In some embodiments, the method 400 may include conveying, via coupling blocks and the multiple cooling conduits, the cooling fluid from the cold plate to one or more satellite cold plates thermally coupled to one or more optical modules of the plurality of optical modules.

The method 400 may include additional embodiments, such as any single embodiment or any combination of embodiments described herein. Although FIG. 4 shows example blocks of the method 400, in some embodiments, the method 400 may include additional blocks, fewer blocks, different blocks, or differently arranged blocks than those depicted in FIG. 4. Additionally, or alternatively, two or more of the blocks of the method 400 may be performed in parallel.

As will be appreciated by one of ordinary skill in the art in view of this disclosure, the present invention may include and/or be embodied as an apparatus (including, for example, a system, a machine, a device, and/or the like), as a method (including, for example, a manufacturing method, a robot-implemented process, and/or the like), or as any combination of the foregoing.

Although many embodiments of the present invention have just been described above, the present invention may be embodied in many different forms and should not be construed as limited to the embodiments set forth herein; rather, these embodiments are provided so that this disclosure will satisfy applicable legal requirements. Also, it will be understood that, where possible, any of the advantages, features, functions, devices, and/or operational aspects of any of the embodiments of the present invention described and/or contemplated herein may be included in any of the other embodiments of the present invention described and/or contemplated herein, and/or vice versa.

While certain exemplary embodiments have been described and shown in the accompanying drawings, it is to be understood that such embodiments are merely illustrative of and not restrictive on the broad invention, and that this invention is not limited to the specific constructions and arrangements shown and described, since various other changes, combinations, omissions, modifications, and substitutions, in addition to those set forth in the above paragraphs, are possible. Those skilled in the art will appreciate that various adaptations, modifications, and combinations of the just described embodiments may be configured without departing from the scope and spirit of the invention. For example, devices, modules, components, and/or elements shown in the figures are not necessarily drawn to scale and may vary from that shown without departing from the scope and spirit of the invention. Therefore, it is to be understood that, within the scope of the appended claims, the invention may be practiced other than as specifically described herein.

What is claimed is:

1. A cooling system, comprising:
a cold plate thermally coupled to a main die, wherein the cold plate defines a fluid inlet and a fluid outlet for receiving and releasing, respectively, a cooling fluid;
a cooling conduit thermally coupling the cold plate to an optical module; and
a coupling block positioned on the cold plate and rotatably supporting the cooling conduit, wherein the coupling block thermally couples the cooling conduit to the cold plate, and wherein the coupling block and the cooling conduit are configured to permit rotation of the cooling conduit between a cooling position in which the cooling conduit is proximate the optical module and an access position in which the cooling conduit is spaced from the optical module.

2. The cooling system of claim 1, wherein:
the cold plate is thermally coupled to a top die surface of the main die, wherein the top die surface is opposite a die attachment surface positioned on a central portion of a surface of a substrate; and
the cooling conduit, when in the cooling position, is thermally coupled to a top module surface of the optical module, wherein the top module surface of the optical module is opposite a module attachment surface positioned on a peripheral portion of the surface of the substrate.

3. The cooling system of claim 1, comprising a satellite plate positioned over a top module surface of the optical module.

4. The cooling system of claim 3, wherein the satellite plate comprises a satellite support, wherein the cooling conduit comprises a heat pipe, and wherein a portion of the heat pipe is positioned between the top module surface and the satellite support.

5. The cooling system of claim 4, wherein the coupling block comprises a pin-and-socket structure configured to receive and rotatably support the heat pipe.

6. The cooling system of claim 3, wherein:
the satellite plate comprises a satellite cold plate;
the cooling conduit comprises a first fluid hose and a second fluid hose;
the coupling block comprises a fluid coupling block configured to provide a portion of the cooling fluid from the fluid inlet of the cold plate to the first fluid hose and to provide the portion of the cooling fluid from the second fluid hose to the fluid outlet of the cold plate; and
the satellite cold plate defines a passage extending therethrough, wherein the first fluid hose is configured to provide the portion of the cooling fluid from the coupling block to a first end of the passage, and wherein the second fluid hose is configured to provide the portion of the cooling fluid from a second end of the passage to the coupling block.

7. The cooling system of claim 1, wherein:
the cooling conduit comprises multiple cooling conduits each thermally coupling the cold plate to a respective optical module of multiple optical modules positioned on a peripheral portion of a surface of a substrate; and
the coupling block comprises multiple coupling blocks each positioned on the cold plate and rotatably supporting a respective cooling conduit of the multiple cooling conduits, wherein each coupling block thermally couples the respective cooling conduit to the cold plate, and wherein each coupling block and its respective cooling conduit are configured to permit rotation of the cooling conduit between a respective cooling position in which the respective cooling conduit is proximate the respective optical module and a respective access position in which the respective cooling conduit is spaced from the respective optical module.

8. The cooling system of claim 7, wherein the multiple cooling conduits comprise heat pipes.

9. The cooling system of claim 1, wherein:
the cooling conduit comprises a first heat pipe;
the coupling block comprises a first coupling block; and
the cooling system comprises:
a second heat pipe thermally coupling the cold plate to the optical module; and
a second coupling block positioned on the cold plate and rotatably supporting the second heat pipe, wherein the second coupling block thermally couples the second heat pipe to the cold plate, and wherein the second coupling block and the second heat pipe are configured to permit rotation of the second heat pipe between a second cooling position in which the second heat pipe is proximate the optical module and a second access position in which the second heat pipe is spaced from the optical module.

10. The cooling system of claim 1, wherein the cooling conduit comprises a closed-loop thermosiphon.

11. The cooling system of claim 1, wherein the coupling block comprises:
an opening for receiving the cooling conduit, wherein the opening has an inner surface adjacent the cooling conduit;
a pair of O-ring seals disposed between the inner surface and the cooling conduit; and
a thermal transfer medium disposed between the O-ring seals and between the inner surface and the cooling conduit.

12. The cooling system of claim 11, comprising one or more interface contacts disposed between the O-ring seals and between an outer surface of the cooling conduit and the thermal transfer medium.

13. The cooling system of claim 11, wherein the thermal transfer medium comprises at least one of liquid metal or thermal grease.

14. The cooling system of claim 11, wherein the thermal transfer medium is sealed within the opening.

15. An electronic module, comprising:
a substrate having a first surface defining a central portion and a peripheral portion;
a main die positioned on the central portion of the first surface;
a plurality of optical modules positioned on the peripheral portion of the first surface;
a cold plate thermally coupled to the main die, wherein the cold plate defines a fluid inlet and a fluid outlet for receiving and releasing, respectively, a cooling fluid;
multiple cooling conduits each thermally coupling the cold plate to an optical module of the plurality of optical modules; and
multiple coupling blocks positioned on the cold plate and rotatably supporting a respective cooling conduit of the multiple cooling conduits, wherein each coupling block thermally couples the respective cooling conduit to the cold plate, and wherein each coupling block and its respective cooling conduit are configured to permit rotation of the respective cooling conduit between a respective cooling position in which the respective cooling conduit is proximate a respective optical module and a respective access position in which the respective cooling conduit is spaced from the respective optical module.

16. The electronic module of claim 15, wherein the multiple cooling conduits comprise heat pipes configured to passively cool the plurality of optical modules.

17. The electronic module of claim 15, comprising a satellite cold plate positioned over top module surfaces of the plurality of optical modules, and wherein the multiple cooling conduits, the satellite cold plate, and the multiple coupling blocks are configured to actively cool the plurality of optical modules using the cooling fluid.

18. The electronic module of claim 15, wherein the multiple cooling conduits comprise closed-loop thermosiphons.

19. A method of cooling components of an electronic module, the method comprising:
thermally coupling a cold plate to a plurality of optical modules positioned on a peripheral portion of a substrate using multiple cooling conduits, wherein the cold plate is thermally coupled to a main die positioned on a central portion of the substrate; and
providing cooling fluid to the cold plate to cool the main die and the plurality of optical modules.

20. The method of claim 19, comprising rotatably coupling a cooling conduit of the multiple cooling conduits to the cold plate such that the cooling conduit is configured to rotate into thermal engagement with one or more optical modules of the plurality of optical modules and away from the one or more optical modules.

21. The method of claim 19, comprising conveying, via coupling blocks and the multiple cooling conduits, the cooling fluid from the cold plate to one or more satellite cold plates thermally coupled to one or more optical modules of the plurality of optical modules.

22. The method of claim 19, wherein each cooling conduit is thermally coupled to the cold plate by a respective coupling block positioned on the cold plate.
